(19) United States
(12) Patent Application Publication
(10) Pub. No.: US 2024/0298472 A1
(43) Pub. Date: Sep. 5, 2024

(54) OLED DISPLAY PANEL, MANUFACTURING METHOD THEREOF, AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Xiao Du, Wuhan (CN); Huai Zhang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/296,228

(22) PCT Filed: Apr. 15, 2021
(86) PCT No.: PCT/CN2021/087391

§ 371 Date: May 19, 2024

(30) Foreign Application Priority Data
Mar. 31, 2021 (CN) 202110345800.7

(51) Int. Cl. H10K 59/122; H10K 59/12; H10K 59/80; H10K 71/20

(52) U.S. Cl. CPC H10K 59/122; H10K 59/1201; H10K 59/80521; H10K 59/873; H10K 71/20

(57) ABSTRACT

An organic electroluminescent display (OLED) panel, a manufacturing method thereof, and a display device are provided. The OLED display panel includes a first display area and a second display area, and further includes a substrate, a pixel definition layer, a spacer layer, a light-emitting layer, and a cathode. The spacer layer includes a plurality of first spacer structures disposed on an isolation structure of the first display area. The light-emitting layer is disposed in pixel openings. The cathode is disposed on the light-emitting layer. In the first display area, the cathode extends to a side surface of the first spacer structures.

### FIELD OF INVENTION

This application relates to display technology, in particular to an organic electroluminescent display (OLED) panel, a manufacturing method thereof, and a display device.

### BACKGROUND OF INVENTION

Organic electroluminescent display (OLED) panels have gradually become mainstream products in a display field due to their excellent performance such as low power consumption, high color saturation, wide viewing angles, thin thickness, and ability to realize flexibility. They can be widely used in terminal products such as smartphones, tablet computers, and televisions.

In recent years, development of mobile terminal market has stimulated the progress of new display technologies. In order to meet requirements of large-screen display and a high screen-to-body ratio of mobile terminals, a full-screen concept is introduced by mobile phone industry over the past two years to increase the screen-to-body ratio of mobile phones. In order to achieve an ideal full-screen display, relevant practitioners all over the world have conducted a lot of theoretical and practical explorations. In mid-2020, products equipped with under-screen imaging technology have been mass-produced, but a lot of shortcomings still exist in this technology. Especially in under-screen camera applications, because light transmittance of the OLED display panels is relatively poor, it is not conducive to ensuring that an under-screen camera has a good shooting effect.

### SUMMARY

### Technical Problem

An objective of the present invention is to provide an organic electroluminescent display (OLED) panel, a manufacturing method thereof, and a display device. A spacer layer and a cathode are sequentially arranged on a pixel definition layer. In an imaging area, a protruding portion of the cathode is removed by a simple process such as mechanical scraping, mechanical adhesion, or laser ablation, so that a regular mesh-shaped cathode pattern is formed in the imaging area under screen. Therefore, a technical problem of low transmittance of the imaging area in the prior art is solved.

### Solution of Problem

### Technical Solution

In order to achieve the objective, the present invention provides an organic electroluminescent display (OLED) display panel including a first display area and a second display area. The OLED display panel further includes: a substrate extending from the first display area to the second display area; a pixel definition layer disposed on the substrate and arranged in the first display area and the second display area, wherein the pixel definition layer includes isolation structures and a pixel opening arranged between adjacent isolation structures; a spacer layer including first spacer structures, each of the first spacer structures is disposed on one of the isolation structures in the first display area; a light-emitting layer disposed in the pixel openings of the first display area and the second display area; and a cathode disposed on the light-emitting layer in the first display area and the second display area, wherein in the first display area, the cathode extends to side surfaces of the first spacer structures.

Further, the OLED display panel further includes an encapsulation layer disposed on a side of the cathode away from the light-emitting layer, wherein the encapsulation layer in the first display area is in direct contact with surfaces of sides of the first spacer structures away from the substrate.

Further, included angles between the side surfaces of the first spacer structures and upper surfaces of the isolation structure range from 8° to 150°.

Further, the spacer layer further includes a second spacer structure correspondingly provided on the isolation structure in the second display area. In the second display area, the cathode extends to a surface of the second spacer structure and covers the second spacer structure, wherein a thickness of the first spacer structure is less than a thickness of the second spacer structure.

Further, included angles between side surfaces of the second spacer structure and upper surfaces of the isolation structures range from 8° to 150°.

Further, an upper surface of the spacer layer is a surface away from the substrate, and an orthographic projection of the first spacer structure or the second spacer structure on the upper surface of the isolation structure completely falls within a boundary of the upper surface of the isolation structure.

Further, the first spacer structure and/or the second spacer structure are/is provided with a slot. The OLED display panel further includes an encapsulation layer disposed on the cathode and filled in the slot, and wherein the encapsulation layer forms a snap portion in the slot.

Further, an area of an orthographic projection of the first spacer structure on the surface of the substrate is defined as a first area, an area of an orthographic projection of the pixel definition layer on the surface of the substrate is defined as a second area, wherein a ratio of the first area to the second area ranges from 5% to 90%.

In order to achieve the objective, the present invention further provides a manufacturing method of an OLED display panel, includes following steps: providing a substrate; forming a pixel definition layer on the substrate; performing a patterning process on the pixel definition layer to form isolation structures, wherein isolation structures are enclosed to form pixel openings; forming a light-emitting layer in the pixel opening; forming a spacer layer on the pixel definition layer; performing a patterning process on the spacer layer to form a semi-finished first spacer structure, wherein an area where the semi-finished first spacer structure is located is defined as a first display area; forming a cathode on the light-emitting layer and the spacer layer, wherein the cathode extends from a surface of the spacer layer to a surface of the light-emitting layer; and in the first display area, performing a thinning process on the semi-finished first spacer structure and removing a portion of the cathode corresponding to a top surface of the semi-finished first spacer structure to form a first spacer structure.

Further, in the step of performing the patterning process on the spacer layer further includes: forming a second spacer structure, wherein an area the second spacer structure is located is defined as a second display area; and in the step of forming the cathode on the light-emitting layer and the spacer layer, the cathode in the second display area extends to a surface of the second spacer structure and covers the second spacer structure.

In order to achieve the objective, the present invention further provides a display device, including the OLED display panel described above.

Further, the display device also includes: an encapsulation layer disposed on a side of the cathode away from the light-emitting layer; wherein the encapsulation layer in the first display area is in direct contact with surfaces of sides of the first spacer structures away from the substrate.

Further, included angles between the side surfaces of the first spacer structures and upper surfaces of the isolation structures range from 8° to 150°.

Further, the spacer layer includes second spacer structures correspondingly provided on the isolation structures of the second display area; in the second display area, the cathode extends to a surface of the second spacer structure and covers the second spacer structure, and a thickness of the first spacer structures is less than a thickness of the second spacer structures.

Further, included angles between side surfaces of the second spacer structures and upper surfaces of the isolation structures range from 8° to 150°.

Further, an upper surface of the spacer layer is a side away from the substrate, and an orthographic projection of the first spacer structure or the second spacer structure on the upper surface of the isolation structure completely falls within a boundary range of the upper surface of the isolation structure.

Further, the first spacer structure and/or the second spacer structure are/is provided with a slot, and the OLED display device further includes an encapsulation layer disposed on the cathode and filled in the slot, and wherein the encapsulation layer forms a snap portion in the slot.

Further, in the second display area, the cathode extends to a surface of the pixel definition layer and covers the pixel definition layer.

Further, in the first display area, an orthographic projection area of the first spacer structure on the surface of the substrate is defined as a first area, an orthographic projection area of the pixel definition layer on the surface of the substrate is defined as a second area, and a ratio of the first area to the second area ranges from 5% to 90%.

### BENEFICIAL EFFECT OF INVENTION

### Beneficial Effect

The technical effect of the present invention is: An organic electroluminescent display (OLED) panel, a manufacturing method thereof, and a display device are provided. The spacer layer is provided in the first display area. A thinning process is performed on a semi-finished first spacer structure by mechanical scraping, mechanical adhesion, or laser ablation, and a portion of the cathode correspondingly disposed on a top surface of the semi-finished first spacer structure is removed to form a first spacer structure, so that the cathode in the first display area forms a regular mesh-shaped cathode pattern. The mesh-shaped cathode pattern is beneficial for further enhancing an overall transmittance of the first display area (under-screen imaging area) without affecting the display effect of the first display area. The present invention may also provide a spacer layer in the second display area, which is beneficial for increasing a contact area between the pixel definition layer and/or the spacer layer and the cathode. Therefore, an adhesion force between the cathode and the substrate is improved, and separation of the film layers during a folding or bending process is avoided.

### BRIEF DESCRIPTION OF DRAWINGS

### Description of Drawings

In order to more clearly describe technical solutions in the embodiments of the present application, following will briefly introduce the drawings that need to be used in the description of the embodiments. Obviously, the drawings in the following description are only some embodiments of the application. For those skilled in the art, other drawings can be obtained based on these drawings without doing creative work.

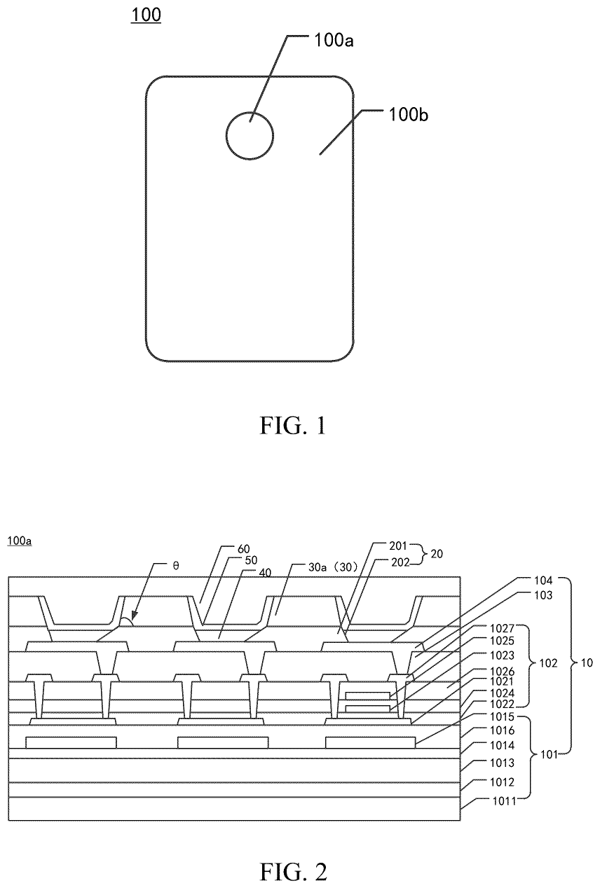

FIG. 1 is a plan view of an organic electroluminescent display (OLED) display panel provided by Embodiment 1 of the present application.

FIG. 2 is a cross-sectional view of a first display area provided by Embodiment 1 of the present application.

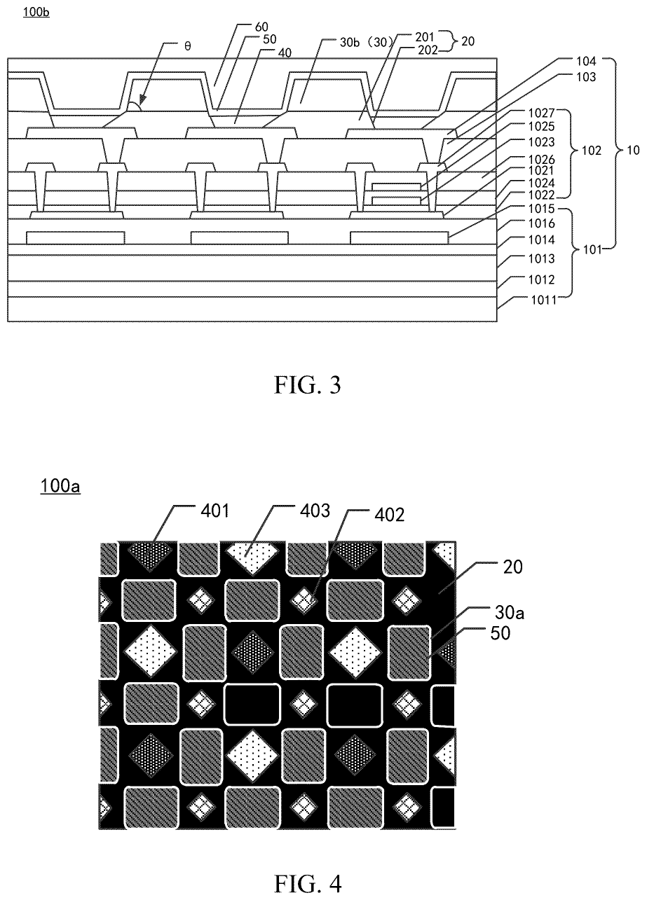

FIG. 3 is a cross-sectional view of a second display area provided by Embodiment 1 of the present application.

FIG. 4 is a plan view of the first display area provided by Embodiment 1 of the present application.

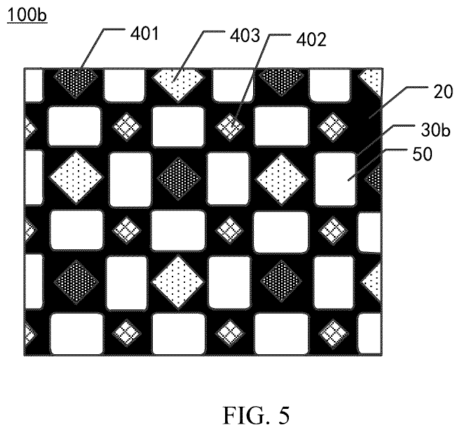

FIG. 5 is a plan view of the second display area provided by Embodiment 1 of the present application.

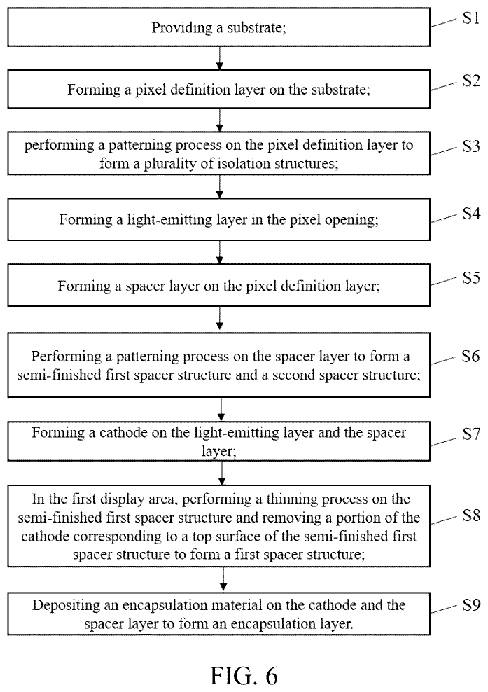

FIG. 6 is a flowchart of a manufacturing method of an OLED display panel provided in Embodiment 1 of the present application.

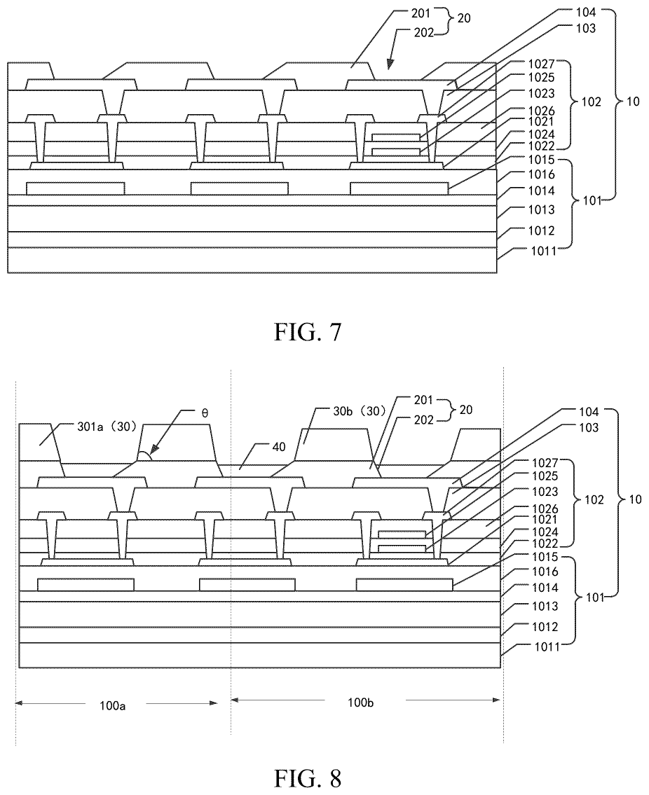

FIG. 7 is a structural schematic diagram after a step of forming a pixel definition layer according to Embodiment 1 of the present application.

FIG. 8 is a structural schematic diagram of a spacer layer after being formed provided by Embodiment 1 of the present application.

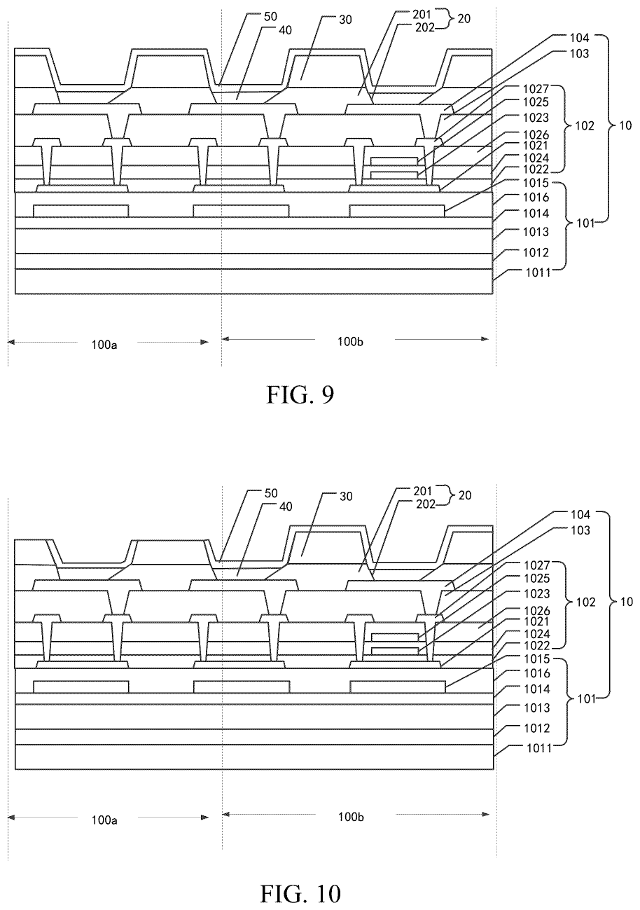

FIG. 9 is a structural schematic diagram of a cathode after being formed provided by Embodiment 1 of the present application.

FIG. 10 is a structural schematic diagram of the cathode after being patterned provided by Embodiment 1 of the present application.

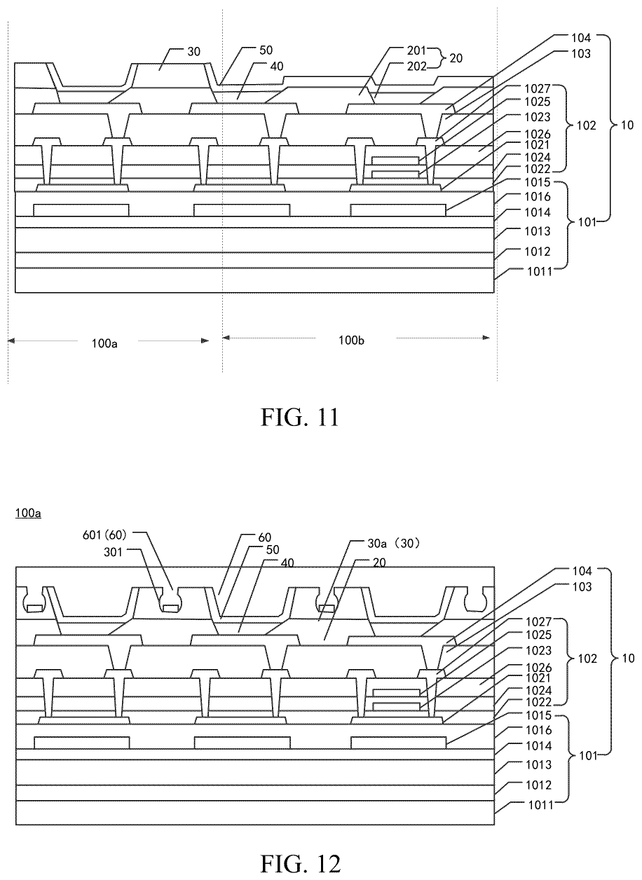

FIG. 11 is a cross-sectional view of an OLED display panel provided by Embodiment 2 of the present application.

FIG. 12 is a cross-sectional view of the first display area provided by Embodiment 3 of the present application.

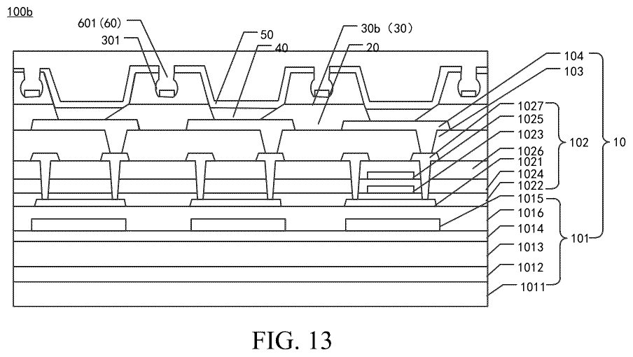

FIG. 13 is a cross-sectional view of the second display area provided by Embodiment 3 of the present application.

### LIST OF REFERENCE NUMBERS

OLED display panel 100, first display area 100a;
Second display area 100b, substrate 10;
Pixel definition layer 20, spacer layer 30;
light-emitting layer 40, cathode 50;
Encapsulation layer 60, first flexible substrate 1011;
First barrier layer 1012, second flexible substrate 1013;
Second barrier layer 1014, light-shielding layer 1015;
Buffer layer 1016, isolation structure 201;
Pixel opening 202, substrate layer 101;
Thin-film transistor layer 102, planarization layer 103;
Anode 104, active layer 1021;
First gate insulating layer 1022, first gate layer 1023;
Second gate insulating layer 1024, second gate layer 1025;
Dielectric layer 1026, source/drain electrode layer 1027;
First spacer structure 30a, second spacer structure 30b;
Red sub-pixel 401, green sub-pixel 402;
Blue sub-pixel 403, slot 301;
Snap portion 601, semi-finished first spacer structure 301a.

### EMBODIMENT OF INVENTION

### Detailed Description of Embodiments

The technical solutions will be clearly and completely described in the embodiments of the present application with reference to drawings. Obviously, the embodiments are only a part of embodiments of the present application, rather than all embodiments. Based on these embodiments in the present application, all other embodiments obtained by those skilled in the art without doing creative work shall fall within the protection scope of the present application. In addition, it should be understood that the specific implementations described here are only used to illustrate and explain the present application rather than limit the present application. In this application, if no explanation is made to the contrary, the orientation words such as “upper” and “lower” usually refer to the upper and lower positions of the device in actual use or working state. Specifically, it refers to the direction in the drawings, and “inner” and “outer” refer to the outline of the device.

The embodiment of the present application provides an OLED display panel and a manufacturing method thereof. Detailed are given below. It should be noted that the description order of the following embodiments does not indicate the preferred order of the embodiments.

### Embodiment 1

FIG. 1 is a plan view of an OLED display panel provided by Embodiment 1 of this application.

As shown in FIG. 1, this embodiment provides an OLED display panel 100, which includes a first display area 100a and a second display area 100b surrounding the first display area 100a.

FIG. 2 is a cross-sectional view of a first display area provided by Embodiment 1 of the present application. FIG. 3 is a cross-sectional view of a second display area provided by Embodiment 1 of the present application.

As shown in FIG. 2 and FIG. 3. The OLED display panel 100 further includes a substrate 10, a pixel definition layer 20, a spacer layer 30, a light-emitting layer 40, a cathode 50, and an encapsulation layer 60.

The substrate 10 extends from the first display area 100a to the second display area 100b.

Specifically, the substrate 10 includes a substrate layer 101, a thin-film transistor layer 102, a planarization layer 103, and an anode 104.

The substrate layer 101 includes a first flexible substrate 1011, a first barrier layer 1012, a second flexible substrate 1013, a second barrier layer 1014, a light-shielding layer 1015, and a buffer layer 1016. The first barrier layer 1012 is disposed on the first flexible substrate 1011. The second flexible substrate 1013 is disposed on the first barrier layer 1012. The second barrier layer 1014 is disposed on the second flexible substrate 1013. The light-shielding layer 1015 is disposed on the second barrier layer 1014. The buffer layer 1016 is disposed on the second barrier layer 1014 and covers the light-shielding layer 1015.

The thin-film transistor layer 102 includes an active layer 1021, a first gate insulating layer 1022, a first gate layer 1023, a second gate insulating layer 1024, a second gate layer 1025, a dielectric layer 1026, and a source/drain electrode layer 1027.

The active layer 1021 is disposed on the buffer layer 1016 and is opposite to the light-shielding layer 1015. The first gate insulating layer 1022 is disposed on the buffer layer 1016 and covers the active layer 1021.

The first gate layer 1023 is disposed on the first gate insulating layer 1022, and having an orthographic projection completely fall within a boundary range where the active layer 1021 is located. The second gate insulating layer 1024 is disposed on the first gate insulating layer 1022 and covers the first gate layer 1023. The second gate layer 1025 is disposed on the second gate insulating layer 1024 and is opposite to the first gate layer 1023. The dielectric layer 1026 is disposed on the second gate insulating layer 1024 and covers the second gate layer 1025. The dielectric layer 1026 may be a single-layer or double-layer inorganic structure. The source/drain electrode layer 1027 penetrates from the dielectric layer 1026 to an upper surface of the active layer 1021.

The pixel definition layer 20 is disposed on the substrate 10 and disposed in the first display area 100a and the second display area 100b. The pixel definition layer 20 has a plurality of isolation structures 201 and pixel openings 202 surrounded by the isolation structures 201.

In the embodiment of the present application, the spacer layer 30 may be disposed in the first display area 100a or disposed in the second display area 100b.

Specifically, the spacer layer 30 has a first spacer structure 30a and a second spacer structure 30b. The first spacer structure 30a is correspondingly disposed on the isolation structure 201 of the first display area 100a. The second spacer structure 30b is correspondingly disposed on the isolation structure 201 of the second display area 100b. Wherein, the thickness of the first spacer structure 30a is less than the thickness of the second spacer structure 30b. An included angle θ between a side surface of the first spacer structure 30a or the second spacer structure 30b and an upper surface of the isolation structure, and the included angle ranges from 8° to 150°. Within this angle range, a cross-sectional topography of the first spacer structure 30a or the second spacer structure 30b is polygonal or other irregular shapes. The polygonal shape may be a trapezoid with a flat top and an arc edge (such as a regular trapezoid or an inverted trapezoid).

It should be noted that the first spacer structure 30a and the second spacer structure 30b may serve as a supporting structure of the OLED display panel 100 to have a supporting effect. The light-emitting layer 40 is disposed in the pixel opening 202 of the first display area 100a and the second display area 100b.

FIG. 4 is a plan view of the first display area provided by Embodiment 1 of the present application. FIG. 5 is a plan view of the second display area provided by Embodiment 1 of the present application.

As shown in FIG. 4 to FIG. 5. The light-emitting layer 40 has a plurality of sub-pixel units, including a red sub-pixel 401, a green sub-pixel 402, and a blue sub-pixel 403. The red sub-pixel 401, the green sub-pixel 402, and the blue sub-pixel 403 are arranged in the pixel opening 202 at intervals by the isolation structure 201. However, because the first spacer structure 30a or the second spacer structure 30b is on the upper surface of the isolation structure 201, the first spacer structure 30a or the second spacer structure 30b is used to separate the three sub-pixels of the red sub-pixel 401, the green sub-pixel 402, and the blue sub-pixel 403, which can be seen with reference to FIG. 2 and FIG. 3. In this embodiment, a planar pattern of the red sub-pixel 401, the green sub-pixel 402, the blue sub-pixel 403, and the first spacer structure 30a or the second spacer structure 30b may be polygonal, circular, or other irregular shapes. The polygonal shape may be rectangular, a rhombic, square, etc., and the circular shape may be an ellipse, an arc, a pearl, etc. It should be noted that the patterns of the red sub-pixel 401, the green sub-pixel 402, and the blue sub-pixel 403 can be matched with the pattern of the first spacer structure 30a or the second spacer structure 30b, as long as the light-emitting effect of the light-emitting layer 40 is not affected.

Please continue to refer to FIG. 2 and FIG. 3. The cathode 50 is disposed on the light-emitting layer 40 in the first display area 100a and the second display area 100b. In the first display area 100a, a light-emitting layer 40 is located between two adjacent first spacer structures 30a. The cathode 50 extends from a sidewall of one of the first spacer structures 30a through a surface of the light-emitting layer 40 to a sidewall of the other first spacer structure 30a. That is, the cathode 50 is disposed on an upper surface of the light-emitting layer 40 and extends to a side surface of the first spacer structure 30a. In the second display area 100b, the cathode 50 extends from the upper surface of the light-emitting layer 40 to a surface of the second spacer structure 30b and covers the second spacer structure 30b.

In the first display area 100a, the encapsulation layer 60 is disposed on an upper surface of the cathode 50 and an upper surface of the first spacer structure 30a. The encapsulation layer 60 is disposed on the cathode 50 in the second display area 100b. The encapsulation layer 60 is used to protect the light-emitting layer 40 and prevent water and oxygen from intruding into the light-emitting layer 40 and affecting the service life.

It should be emphasized that in this embodiment, the upper surface of the spacer layer 30 is a side away from the substrate 10. An orthographic projection of the first spacer structure 30a or the second spacer structure 30b on the upper surface of the isolation structure 201 completely falls within a boundary range of the upper surface of the isolation structure 201. This is beneficial for ensuring that the sub-pixel units in each pixel opening 202 will not be partially or completely covered by the first spacer structure 30a or the second spacer structure 30b, thereby improving the light-emitting effect of the OLED display panel 100.

In the first display area 100a, an orthographic projection area of the first spacer structure 30a on the surface of the substrate 10 is defined as a first area S1, an orthographic projection area of the pixel definition layer 20 on the surface of the substrate 10 is defined as a second area S2, and a ratio of the first area S1 to the second area S2 ranges from 5% to 90%. This is beneficial for improving the light-emitting effect at any position of the first display area 100a, thereby enhancing the transmittance of the first display area 100a.

Similarly, in the second display area 100b, an orthographic projection area of the second spacer structure 30b on the surface of the substrate 10 is defined as a third area S3, an orthographic projection area of the pixel definition layer 20 on the surface of the substrate 10 is defined as a fourth area S4, and a ratio of the third area S3 to the fourth area S4 ranges from 5% to 90%. This is beneficial for improving the light-emitting effect at any position of the second display area 100b, thereby enhancing the transmittance of the second display area 100b.

Taken as a whole, in this embodiment, an orthographic projection area of the spacer layer 30 on the surface of the substrate 10 is defined as a fifth area S5, an orthographic projection area of the pixel definition layer 20 on the surface of the substrate 10 is defined as a sixth area S6, and a ratio of the fifth area S5 to the sixth area S6 ranges from 5% to 90%. This is beneficial for improving the light-emitting effect of any position of the OLED display panel 100, thereby enhancing the overall transmittance of the OLED display panel 100.

It should be noted that the first display area 100a is an imaging area, and the second display area 100b is an active area (AA area). When the first display area 100a is an imaging area, and the thickness of the first spacer structure 30a is less than the thickness of the second spacer structure 30b, it is beneficial to enhance the overall transmittance of the under-screen imaging area. Preferably, the thickness of the first spacer structure 30a ranges from 0.5 μm to 10 μm, and the thickness of the second spacer structure 30b ranges from 4 μm to 12 μm.

The spacer layer 30 is provided in the first display area 100a. A thinning process is performed on the semi-finished first spacer structure 30a by mechanical scraping, mechanical adhesion, or laser ablation, and a portion of the cathode 50 correspondingly disposed on the top surface of the semi-finished first spacer structure 30a is removed to form a first spacer structure 30a, so that the cathode 50 in the first display area forms a regular mesh-shaped cathode pattern, such as a grid structure. As shown in FIG. 4, the grid structure is beneficial for further enhancing the overall transmittance of the first display area 100a (under-screen imaging area) without affecting the display effect of the first display area 100a. Providing the spacer layer 30 in the second display area 100b is beneficial for increasing the contact area between the pixel definition layer 20 and/or the spacer layer 30 and the cathode 50. Therefore, the adhesion force between the cathode 50 and the substrate 10 is improved, and film layer separation during a folding or bending process can be avoided.

It should be emphasized that when the thinning process is performed on the semi-finished first spacer structure 30a by laser ablation, and the portion of the cathode 50 on the top surface of the semi-finished first spacer structure 30a is removed, a certain degree of protection to the lines under the spacer layer 30 can be provided and the yield of forming the mesh-shaped cathode pattern by laser ablation can be improved. In this embodiment, the design of disposing the spacer layer 30 on the pixel definition layer 20 can be achieved through simple mask modification and film layer addition, which overcomes current technical difficulties in the under-screen imaging area and further improves the overall transmittance of the imaging area.

The encapsulation layer 60 is disposed on the cathode 50 and extends from the first display area 100a to the second display area 100b. In the first display area 100a, the encapsulation layer 60 directly contacts a side surface of the first spacer structure 30a away from the substrate 10. In the second display area 100 b, the encapsulation layer 60 is attached to the cathode 50. In this embodiment, when the encapsulation layer 60 is attached to the first spacer structure 30a, it is beneficial for improving the adhesion of the encapsulation layer 60 when it is deposited on the first spacer structure 30a.

FIG. 6 is a flowchart of a manufacturing method of an OLED display panel provided by Embodiment 1 of the present application.

As shown in FIG. 6, this embodiment further provides a manufacturing method of an OLED display panel, which includes the following steps S1-S9.

S1, providing a substrate.

As shown in FIG. 2-FIG. 3, the substrate 10 includes a substrate layer 101, a thin film transistor layer 102, a planarization layer 103, and an anode 104.

The substrate layer 101 includes a first flexible substrate 1011, a first barrier layer 1012, a second flexible substrate 1013, a second barrier layer 1014, a light-shielding layer 1015, and a buffer layer 1016. The first barrier layer 1012 is disposed on the first flexible substrate 1011. The first barrier layer 1012 is disposed on the first flexible substrate 1011. The second barrier layer 1014 is disposed on the second flexible substrate 1013. The light-shielding layer 1015 is provided on the second barrier layer 1014. The buffer layer 1016 is disposed on the second barrier layer 1014 and covers the light-shielding layer 1015.

The thin-film transistor layer 102 includes an active layer 1021, a first gate insulating layer 1022, a first gate layer 1023, a second gate insulating layer 1024, a second gate layer 1025, a dielectric layer 1026, and a source/drain electrode layer 1027.

The active layer 1021 is disposed on the buffer layer 1016 and is opposite to the light-shielding layer 1015. The first gate insulating layer 1022 is disposed on the buffer layer 1016 and covers the active layer 1021.

The first gate layer 1023 is disposed on the first gate insulating layer 1022, and having an orthographic projection completely fall within the range where the active layer 1021 is located. The second gate insulating layer 1024 is disposed on the first gate insulating layer 1022 and covers the first gate layer 1023. The second gate layer 1025 is disposed on the second gate insulating layer 1024 and is opposite to the first gate layer 1023. The dielectric layer 1026 is disposed on the second gate insulating layer 1024 and covers the second gate layer 1025. The dielectric layer 1026 may be a single-layer or double-layer inorganic structure. The source/drain electrode layer 1027 penetrates from the dielectric layer 1026 to the upper surface of the active layer 1021.

S2, forming a pixel definition layer on the substrate.

S3, performing a patterning process on the pixel definition layer to form a plurality of isolation structures, wherein the isolation structures are enclosed to form pixel openings.

FIG. 7 is a structural schematic diagram after a step of forming the pixel definition layer according to Embodiment 1 of the application.

Specifically, as shown in FIG. 7, the pixel definition layer 20 is patterned by using methods such as exposure and development. The pixel definition layer 20 has the plurality of isolation structures 201 and pixel openings 202 enclosed and formed by the isolation structures 201.

S4, forming the light-emitting layer in the pixel opening.

Please refer to FIG. 2 to FIG. 3, an organic material (such as an organic quantum dot material) is deposited in the pixel opening 202 to form the light-emitting layer 40. The light-emitting layer 40 has a plurality of sub-pixel units, including red sub-pixels, green sub-pixels, and blue sub-pixels. The red sub-pixels, the green sub-pixels, and the blue sub-pixels are arranged in the pixel opening 202 at intervals by the isolation structure 201.

S5, forming the spacer layer on the pixel definition layer.

S6, performing the patterning process on the spacer layer to form the semi-finished first spacer structure and a second spacer structure, wherein an area where the semi-finished first spacer structure is located is defined as the first display area, and an area where the semi-finished second spacer structure is located is defined as the second display area.

FIG. 8 is a structural schematic diagram of a spacer layer after being formed provided by Embodiment 1 of the present application.

As shown in FIG. 8, the spacer layer 30 is patterned by methods such as exposure and development, so that the spacer layer 30 has the semi-finished first spacer structure 301a and a second spacer structure 30b.

S7, forming a cathode on the light-emitting layer and the spacer layer, wherein the cathode extends from the surface of the spacer layer to the surface of the light-emitting layer.

FIG. 9 is a structural schematic diagram of the cathode after being formed provided by Embodiment 1 of the present application.

Specifically, as shown in FIG. 9, metal materials (such as copper, molybdenum, or aluminum, etc.) or other metal oxide materials are deposited on the light-emitting layer 40 and the spacer layer 30 to form the cathode 50.

S8, in the first display area, performing the thinning process on the semi-finished first spacer structure and removing a portion of the cathode corresponding to a top surface of the semi-finished first spacer structure to form a first spacer structure.

As shown in FIG. 10. FIG. 10 is a structural schematic diagram of the cathode after being patterned provided in Embodiment 1 of the present application.

Alignment is completed with a charge-coupled device (CCD) in a CUP processing chamber, and the thinning process is performed on the semi-finished first spacer structure 30a by anyone of mechanical scraping, mechanical adhesion, or laser ablation, and a portion of the cathode 50 correspondingly disposed on the top surface of the semi-finished first spacer structure is removed, so that the thickness of the first spacer structure 30a is less than the thickness of the second spacer structure 30b. Wherein, in the first display area 100a, the cathode 50 extends to the side surface of the first spacer structure 30a, and in the second display area 100b, the cathode 50 extends to the surface of the second spacer structure 30b and covers the second spacer structure 30b.

Specifically, the first spacer structure 30a is correspondingly disposed on the isolation structure 201 of the first display area 100a, and the second spacer structure 30b is correspondingly disposed on the isolation structure 201 of the second display area 100b. An included angle θ between an upper surface of the isolation structure and a side surface of the first spacer structure 30a or the second spacer structure 30b, and the included angle ranges from 8° to 150°. Within this angle range, a cross-sectional topography of the first spacer structure 30a or the second spacer structure 30b is polygonal or other irregular shapes. The polygonal shape may be a trapezoid with a flat top and an arc edge (such as a regular trapezoid, or an inverted trapezoid).

The cathode 50 is disposed on the light-emitting layer 40 of the first display area 100a and the second display area 100b. In the first display area 100a, the cathode 50 extends to a side of the first spacer structure 30a, and in the second display area 100b, the cathode 50 extends to the surface of the second spacer structure 30b and covers the second spacer structure 30b.

It should be emphasized that in this embodiment, the upper surface of the spacer layer 30 is a side away from the substrate 10, and an orthographic projection of the first spacer structure 30a or the second spacer structure 30b on the upper surface of the isolation structure 201 completely falls within the boundary range of the upper surface of the isolation structure 201. This is beneficial to ensure that the sub-pixel units in each pixel opening 202 will not be partially or completely covered by the first spacer structure 30a or the second spacer structure 30b, thereby improving the light-emitting effect of the OLED display panel 100.

In the first display area 100a, an orthographic projection area of the first spacer structure 30a on the surface of the substrate 10 is defined as a first area S1, an orthographic projection area of the pixel definition layer 20 on the surface of the substrate 10 is defined as a second area S2, and a ratio of the first area S1 to the second area S2 ranges from 5% to 90%. This is beneficial for improving the light-emitting effect at any position of the first display area 100a, thereby enhancing the transmittance of the first display area 100a.

Similarly, in the second display area 100b, an orthographic projection area of the second spacer structure 30b on the surface of the substrate 10 is defined as a third area S3, an orthographic projection area of the pixel definition layer 20 on the surface of the substrate 10 is defined as a fourth area S4, and a ratio of the third area S3 to the fourth area S4 ranges from 5% to 90%. This is beneficial for improving the light-emitting effect at any position of the second display area 100b, thereby enhancing the transmittance of the second display area 100b.

Taken as a whole, in this embodiment, the orthographic projection area of the spacer layer 30 on the surface of the substrate 10 is defined as a fifth area S5, an orthographic projection area of the pixel definition layer 20 on the surface of the substrate 10 is defined as a sixth area S6, and a ratio of the fifth area S5 to the sixth area S6 ranges from 5% to 90%. This is beneficial for improving the light-emitting effect of any position of the OLED display panel 100, thereby enhancing the overall transmittance of the OLED display panel 100.

It should be noted that the first display area 100a is an imaging area, and the second display area 100b is an active area (AA area). When the first display area 100a is an imaging area, and the thickness of the first spacer structure 30a is less than the thickness of the second spacer structure 30b, it is beneficial for enhancing the overall transmittance of the under-screen imaging area. Preferably, the thickness of the first spacer structure 30a ranges from 0.5 μm to 10 μm, and the thickness of the second spacer structure 30b ranges from 4 μm to 12 μm.

S9, depositing an encapsulation material on the cathode and the spacer layer to form the encapsulation layer.

Please continue to refer to FIG. 2 and FIG. 3. An encapsulating material, such as an inorganic material or an organic material, is deposited on the cathode 50 to form at least one stacked inorganic film layer or organic film layer to protect the light-emitting layer 40 and prevent water and oxygen from intruding into the light-emitting layer 40 and affecting its service life.

In the first display area 100a, the encapsulation layer 60 directly contacts the side surface of the first spacer structure 30a away from the substrate 10. In the second display area 100b, the encapsulation layer 60 is attached to the cathode 50. In this embodiment, when the encapsulation layer 60 is attached to the first spacer structure 30a, it is beneficial for improving the adhesion of the encapsulation layer 60 when it is deposited on the first spacer structure 30a.

This embodiment provides a manufacturing method of an OLED display panel. The spacer layer 30 is provided in the first display area 100a. The thinning process is performed on the semi-finished first spacer structure 30a by mechanical scraping, mechanical adhesion, or laser ablation, and a portion of the cathode 50 correspondingly disposed on the top surface of the semi-finished first spacer structure 30a is removed to form a first spacer structure 30a, so that the cathode 50 in the first display area forms a regular mesh-shaped cathode pattern, such as a grid structure. As shown in FIG. 4, the grid structure is beneficial for further enhancing the overall transmittance of the first display area 100a (under-screen imaging area) without affecting the display effect of the first display area 100a. Providing the spacer layer 30 in the second display area 100b is beneficial for increasing the contact area between the pixel definition layer 20 and/or the spacer layer 30 and the cathode 50. Therefore, the adhesion force between the cathode 50 and the substrate 10 is improved, and the film layer separation during a folding or bending process can be avoided.

Compared with prior art, on one hand, this embodiment can achieve precise patterning of the cathode through simple structural changes and simpler equipment and manufacturing processes. In addition, the shortcomings of insufficient accuracy and stability in the prior art can be avoided, and the transmittance of the first display area 100a (under-screen imaging area) can be enhanced without affecting the display effect of this area. On the other hand, the cathode pattern of this embodiment can be changed according to design of photomask, which can support the application of under-screen cameras with various pixel arrangements.

This embodiment further provides a display device, which includes the aforementioned OLED display panel. The display device can be any product or component with a display function, such as electronic paper, mobile phone, tablet computer, television, monitor, notebook computer, digital photo frame, navigator, etc.

### Embodiment 2

This embodiment provides an OLED display panel, a manufacturing method thereof, and a display device, including most of the technical solutions of Embodiment 1. The difference is that the spacer layer is only arranged in the first display area.

FIG. 11 is a cross-sectional view of an OLED display panel provided by Embodiment 2 of the present application.

Specifically, as shown in FIG. 11, the spacer layer 30 has a first spacer structure 30a, and the first spacer structure 30a is correspondingly disposed on the isolation structure 201 in the first display area 100a. The light-emitting layer 40 is disposed in the pixel opening 202 of the first display area 100a and the second display area 100b. The cathode 50 is disposed on the light-emitting layer 40 in the first display area 100a and the second display area 100b. In the first display area 100a, a light-emitting layer 40 is located between two adjacent first spacer structures 30a. The cathode 50 extends from a sidewall of one of the first spacer structures 30a through a surface of the light-emitting layer 40 to a sidewall of the other first spacer structure 30a. That is, the cathode 50 is disposed on the upper surface of the light-emitting layer 40 and extends to the side surface of the first spacer structure 30a. In the second display area 100b, the cathode 50 extends from the upper surface of the light-emitting layer 40 to the surface of the second spacer structure 30b and covers the second spacer structure 30b.

This embodiment provides an OLED display panel, a manufacturing method thereof, and a display device. The spacer layer is provided in the first display area. A thinning process is performed on the semi-finished first spacer structure by mechanical scraping, mechanical adhesion, or laser ablation, and a portion of the cathode correspondingly disposed on the top surface of the semi-finished first spacer structure is removed to form a first spacer structure, so that the cathode in the first display area forms a regular mesh-shaped cathode pattern. The mesh-shaped cathode pattern is beneficial for further enhancing the overall transmittance of the first display area (under-screen imaging area) without affecting the display effect of the first display area.

### Embodiment 3

This embodiment provides an OLED display panel, a manufacturing method thereof, and a display device, including all technical solutions of Embodiment 1 or Embodiment 2. The difference is that the spacer layer is provided with a slot.

FIG. 12 is a cross-sectional view of the first display area provided by Embodiment 3 of the present application.

As shown in FIG. 12 and FIG. 13, this embodiment provides an OLED display panel. Both the first spacer structure 30a and the second spacer structure 30b are provided with a slot 301. The encapsulation layer 60 is disposed on the cathode 50 and in the slot 301, wherein the encapsulation layer 60 forms a snap portion 601 in the slot.

Specifically, in the first display area 100a, the encapsulation layer 60 is disposed on the upper surface of the cathode 50 and the first spacer structure 30a and fills the slot 301 to form the snap portion 601. In the second display area 100b, the encapsulation layer 60 is disposed on the cathode 50 and fills the slot 301 to form the snap portion 601. In this embodiment, the snap portion 601 is used to improve the adhesion of the encapsulation layer 60 when it is deposited on the spacer layer 30. In addition, compactness between the encapsulation layer 60, the spacer layer 30, and the cathode 50 is improved, so as to better protect the light-emitting layer 40.

This embodiment provides a manufacturing method of an OLED display panel. The difference between this embodiment and Embodiment 1 is that the step of patterning the spacer layer further includes performing a drilling process on the spacer layer so that both the semi-finished first spacer structure and the second spacer structure have the slot 301.

In the step of forming the cathode on the light-emitting layer and the spacer layer, the cathode 50 is disposed in the slot 301.

In the step of depositing the encapsulation material on the cathode and the spacer layer, an encapsulation layer 60 is formed on the cathode 50, wherein the encapsulation material fills the slot 301 to form the snap portion 601.

Specifically, in the first display area 100a, the encapsulation layer 60 is disposed on the upper surface of the cathode 50 and the first spacer structure 30a and fills the slot 301 to form the snap portion 601. In the second display area 100b, the encapsulation layer 60 is disposed on the cathode 50 and fills the slot 301 to form the snap portion 601. In this embodiment, the snap portion 601 is used to improve the adhesion of the encapsulation layer 60 when it is deposited on the spacer layer 30. In addition, the compactness between the encapsulation layer 60, the spacer layer 30, and the cathode 50 is improved, so as to better protect the light-emitting layer 40.

The OLED display panel and the manufacturing method thereof provided by the embodiments of the present application are described in detail above. In this article, specific examples are used to explain the principles and implementation of this application. The description of the embodiment is only used to help understand the method and core idea of this application. In addition, for those skilled in the art, according to the idea of this application, there will be changes in the specific implementation and the scope of this application. As mentioned above, the content of this specification should not be construed as a limitation to this application.

1. An OLED display panel comprising a first display area and a second display area, wherein the OLED display panel further comprises:
a substrate extending from the first display area to the second display area;
a pixel definition layer disposed on the substrate and arranged in the first display area and the second display area, wherein the pixel definition layer comprises isolation structures and pixel openings arranged between adjacent isolation structures;
a spacer layer comprising first spacer structures, each of the first spacer structures is disposed on one of the isolation structures in the first display area;
a light-emitting layer disposed in the pixel openings of the first display area and the second display area; and
a cathode disposed on the light-emitting layer in the first display area and the second display area, wherein in the first display area, the cathode extends to side surfaces of the first spacer structures.

2. The OLED display panel according to claim 1, further comprising:
an encapsulation layer disposed on a side of the cathode away from the light-emitting layer;
wherein the encapsulation layer in the first display area is in direct contact with surfaces of sides of the first spacer structures away from the substrate.

3. The OLED display panel according to claim 1, wherein included angles between the side surfaces of the first spacer structures and upper surfaces of the isolation structures range from 8° to 150°.

4. The OLED display panel according to claim 1, wherein the spacer layer further comprises a second spacer structure correspondingly provided on the isolation structure in the second display area; and
in the second display area, the cathode extends to a surface of the second spacer structures and covers the second spacer structures, and a thickness of the first spacer structure is less than a thickness of the second spacer structures.

5. The OLED display panel according to claim 4, wherein included angles between side surfaces of the second spacer structures and upper surfaces of the isolation structures range from 8° to 150°.

6. The OLED display panel according to claim 4, wherein an upper surface of the spacer layer is a surface away from the substrate, and an orthographic projection of the first spacer structure or the second spacer structure on the upper surface of the isolation structure completely falls within a boundary of the upper surface of the isolation structure.

7. The OLED display panel according to claim 4, wherein the first spacer structure and/or the second spacer structure are/is provided with a slot, and
the OLED display panel further comprises an encapsulation layer disposed on the cathode and filled in the slot, and the encapsulation layer forms an engagement portion in the slot.

8. The OLED display panel according to claim 1, wherein in the second display area, the cathode extends to a surface of the pixel definition layer and covers the pixel definition layer.

9. The OLED display panel according to claim 1, wherein in the first display area, an area of an orthographic projection of the first spacer structure on a surface of the substrate is defined as a first area, an area of an orthographic projection of the pixel definition layer on the surface of the substrate is defined as a second area, and a ratio of the first area to the second area ranges from 5% to 90%.

10. A manufacturing method of an OLED display panel, comprising following steps:
providing a substrate;
forming a pixel definition layer on the substrate;
performing a patterning process on the pixel definition layer to form isolation structures, wherein the isolation structures are enclosed to form pixel openings;
forming a light-emitting layer in the pixel openings;
forming a spacer layer on the pixel definition layer;
performing a patterning process on the spacer layer to form a semi-finished first spacer structure, wherein an area the semi-finished first spacer structure is located is defined as a first display area;
forming a cathode on the light-emitting layer and the spacer layer, wherein the cathode extends from a surface of the spacer layer to a surface of the light-emitting layer; and
in the first display area, performing a thinning process on the semi-finished first spacer structure and removing a portion of the cathode corresponding to a top surface of the semi-finished first spacer structure to form a first spacer structure.

11. The manufacturing method of the OLED display panel according to claim 10, wherein the step of performing the patterning process on the spacer layer further comprises:
forming a second spacer structure, wherein an area the second spacer structure is located is defined as a second display area; and
in the step of forming the cathode on the light-emitting layer and the spacer layer, the cathode in the second display area extends to a surface of the second spacer structure and covers the second spacer structure.

12. A display device, comprising the OLED display panel according to claim 1.

13. The display device according to claim 12, further comprising:
an encapsulation layer disposed on a side of the cathode away from the light-emitting layer;
wherein, the encapsulation layer in the first display area is in direct contact with a surface of the first spacer structure away from the substrate.

14. The display device according to claim 12, wherein included angles between a side surfaces of the first spacer structures and upper surfaces of the isolation structures range from 8° to 150°.

15. The display device according to claim 12, wherein the spacer layer further comprises second spacer structures correspondingly provided on the isolation structures in the second display area; and
in the second display area, the cathode extends to a surface of the second spacer structure and covers the second spacer structure, and a thickness of the first spacer structure is smaller than a thickness of the second spacer structure.

16. The display device according to claim 15, wherein included angles between side surfaces of the second spacer structures and upper surfaces of the isolation structures range from 8° to 150°.

17. The display device according to claim 15, wherein an upper surface of the spacer layer is a surface away from the substrate, and an orthographic projection of the first spacer structure or the second spacer structure on the upper surface of the isolation structure completely falls within a boundary of the upper surface of the isolation structure.

18. The display device according to claim 15, wherein the first spacer structure and/or the second spacer structure are/is provided with a slot, and
the display device further comprises an encapsulation layer disposed on the cathode and filled in the slot, and wherein the encapsulation layer forms an engagement portion in the slot.

19. The display device according to claim 12, wherein in the second display area, the cathode extends to a surface of the pixel definition layer and covers the pixel definition layer.

20. The display device according to claim 12, wherein in the first display area, an area of an orthographic projection of the first spacer structure on a surface of the substrate is defined as a first area, an area of an orthographic projection of the pixel definition layer on the surface of the substrate is defined as a second area, and a ratio of the first area to the second area ranges from 5% to 90%.
